(19) United States
(12) Patent Application Publication
(10) Pub. No.: US 2017/0084644 A1
(43) Pub. Date: Mar. 23, 2017

(54) THIN FILM TRANSISTOR ARRAY PANEL AND MANUFACTURING METHOD THEREOF

(71) Applicant: Samsung Display Co., Ltd., Yongin-si (KR)

(72) Inventors: Sang Hyun KANG, Hwaseong-si (KR); Hyung Joo JEON, Suwon-si (KR); Hyung June KIM, Anyang-si (KR); Min Jae BAEK, Yongin-si (KR); Hyun-Woong BAEK, Seoul (KR); Wan-Soon IM, Cheonan-si (KR); Jang-Bog JU, Seongnam-si (KR); Kang Wook HEO, Cheonan-si (KR)

(21) Appl. No.: 15/187,392

(22) Filed: Jun. 20, 2016

(30) Foreign Application Priority Data
Sep. 22, 2015 (KR) 10-2015-0134063

(51) Int. Cl. H01L 27/12

(52) U.S. Cl. CPC H01L 27/1288; H01L 27/124; H01L 27/1248

(57) ABSTRACT

Disclosed is a thin film transistor array panel including: a substrate; a gate line provided on the substrate and extending in a first direction; a data line extending in a second direction; a first light blocking member provided on the gate line and the data line and overlapping the gate line; and a second light blocking member overlapping the data line, wherein the first and second light blocking members respectively include a flat portion and an inclined portion having different average thicknesses in a third direction that is vertical to the first direction and second direction, the inclined portion has a slanted side at an external portion of the flat portion, and a width of the inclined portion of the first light blocking member in the second direction is less than half the width of the second light blocking member in the first direction.

### CROSS-REFERENCE TO RELATED APPLICATION

This application claims priority to and the benefit of Korean Patent Application No. 10-2015-0134063 filed in the Korean Intellectual Property Office on Sep. 22, 2015, the entire contents of which are incorporated herein by reference.

### BACKGROUND

(a) Field

The present disclosure relates to a thin film transistor array panel and a manufacturing method thereof.

(b) Description of the Related Art

When a liquid crystal display includes two display panels facing each other, a pixel electrode of the field generating electrodes to which a data voltage is applied and a plurality of thin film transistors may be arranged in a matrix form on one of the display panels facing each other, and a color filter for representing primary colors, such as red, green, and blue, and a light blocking member for preventing light leakage between pixels may be formed on the other display panel.

However, in the liquid crystal display described above, since the pixel electrode, the thin film transistors, and the color filter or the light blocking member are formed in different display panels, it is difficult to achieve an accurate alignment between the pixel electrode and the color filter or between the pixel electrode and the light blocking member, thereby potentially causing an alignment error.

To solve this problem, a structure for forming the light blocking member in the same display panel in which the pixel electrode and the thin film transistor are formed has been proposed. In this case, the color filter may be formed in the same display panel as the pixel electrode. As such, the light blocking member may be integrally formed in the display panel in which the pixel electrode and the thin film transistor are formed, thereby achieving a high aperture ratio and high transmittance of the liquid crystal display.

The above information disclosed in this Background section is only to enhance the understanding of the background of the disclosure and therefore, it may contain information that does not form the prior art that is already known in this country to a person of ordinary skill in the art.

### SUMMARY

The present disclosure provides a thin film transistor array panel for preventing light leakage and transmittance deterioration of a display device caused by a residual region of a light blocking member, along with a manufacturing method thereof.

An exemplary embodiment of the present disclosure provides a thin film transistor array panel including: a substrate; a gate line provided on the substrate and extending in a first direction; a data line extending in a second direction; a first light blocking member provided on the gate line and the data line and overlapping the gate line; and a second light blocking member overlapping the data line, wherein the first and second light blocking members respectively include a flat portion and an inclined portion having different average thicknesses in a third direction that is vertical to the first direction and second direction, the inclined portion has a slanted side at an external portion of the flat portion, and a width of the inclined portion of the first light blocking member in the second direction is less than half the width of the second light blocking member in the first direction.

A width of the inclined portion of the second light blocking member in the first direction may be less than half the width of the second light blocking member in the first direction.

An upper side of the flat portion may be substantially flat, and a thickness of the inclined portion in the third direction may be reduced when approaching the outermost edges of the first and second light blocking members from a portion provided near the flat portion.

The first light blocking member may include a column spacer having a thickness in the third direction that is greater than the inclined portion and the flat portion.

The column spacer may include a main column spacer and a sub column spacer, and a thickness of the main column spacer in the third direction may be greater than a thickness of the sub column spacer in the third direction.

The column spacer may be integrated with the first and second light blocking members.

The column spacer may include the same material as the light blocking member.

Another embodiment of the present disclosure provides a method for manufacturing a thin film transistor array panel including: forming a gate line in a first direction and a data line in a second direction on a substrate; forming a light blocking material layer on an entire side of the substrate; and forming a first light blocking member and a second light blocking member including a flat portion and an inclined portion having different average thicknesses in a third direction that is vertical to the first direction and the second direction by exposure using a mask, wherein the first light blocking member overlaps the gate line and the second light blocking member overlaps the data line, the inclined portion has a slanted side on an external portion of the flat portion, and the mask transmits part of the light and includes a first transflective region and a second transflective region with different light transmittances.

A width of the inclined portion of the first light blocking member in the second direction may be formed to be less than half the width of the second light blocking member in the first direction, and a width of the inclined portion of the second light blocking member in the first direction may be less than half the width of the second light blocking member in the first direction.

The second transflective region may be formed along an edge of the first transflective region, and light transmittance of the first transflective region may be greater than light transmittance of the second transflective region.

The first transflective region may correspond to the flat portion, and the second transflective region may correspond to the inclined portion.

Light transmittance of the first transflective region may be substantially 14 to 18%, and light transmittance of the second transflective region may be substantially 7 to 11%.

The forming of a first light blocking member may include forming a column spacer having a height in the third direction that is greater than those of the inclined portion and the flat portion of the first light blocking member.

The mask may further include a light transmitting region for transmitting the entire light, and the light transmitting region may correspond to the column spacer.

The method may further include forming a color filter on the substrate before the forming of a light blocking material layer.

According to exemplary embodiments of the thin film transistor array panel and the manufacturing method thereof disclosed herein, the residual region of the light blocking member may be minimized to prevent light leakage of the display device and improve transmittance.

### BRIEF DESCRIPTION OF THE DRAWINGS

FIG. 1 shows a top plan view of a thin film transistor array panel according to an exemplary embodiment of the present disclosure.

FIG. 2 shows a cross-sectional view of a thin film transistor array panel shown in FIG. 1 with respect to line II-II.

FIG. 3 shows a cross-sectional view of a thin film transistor array panel shown in FIG. 1 with respect to line III-III.

FIG. 4 shows a cross-sectional view of a thin film transistor array panel shown in FIG. 1 with respect to line IV-IV.

FIG. 5 and FIG. 6 show a process for forming a light blocking member of a thin film transistor array panel according to an exemplary embodiment of the present disclosure. In particular, they show cross-sectional views of a thin film transistor array panel shown in FIG. 1 with respect to line V-V.

FIG. 7 shows a top plan view of a pixel of a liquid crystal display according to an exemplary embodiment of the present disclosure.

FIG. 8 shows a cross-sectional view of a liquid crystal display shown in FIG. 7 with respect to line VIII-VIII.

FIG. 9 shows a cross-sectional view of a liquid crystal display shown in FIG. 7 with respect to line IX-IX.

FIG. 10 shows a cross-sectional view of a liquid crystal display shown in FIG. 7 with respect to line X-X.

### DETAILED DESCRIPTION OF THE EMBODIMENTS

The present disclosure is described more fully hereinafter with reference to the accompanying drawings, in which exemplary embodiments of the disclosure are shown. As those skilled in the art would realize, the described embodiments may be modified in various different ways, all without departing from the spirit or scope of the present disclosure.

In the drawings, the thickness and other dimensions of layers, films, panels, regions, etc., may be exaggerated for clarity. Like reference numerals designate like elements throughout the specification. It will be understood that when an element such as a layer, film, region, or substrate is referred to as being “on” another element, it may be directly on the other element, or intervening elements may also be present. In contrast, when an element is referred to as being “directly on” another element, there are no intervening elements present.

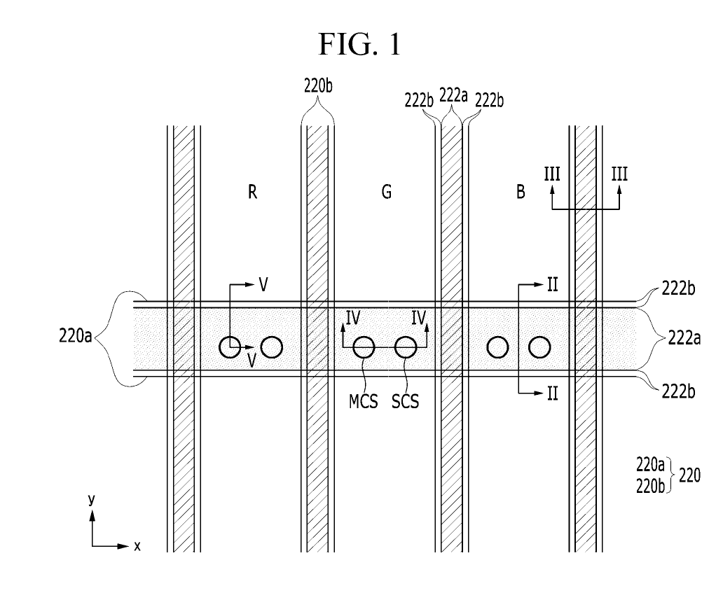

A thin film transistor array panel according to an exemplary embodiment of the present disclosure is now described with reference to FIG. 1 to FIG. 4.

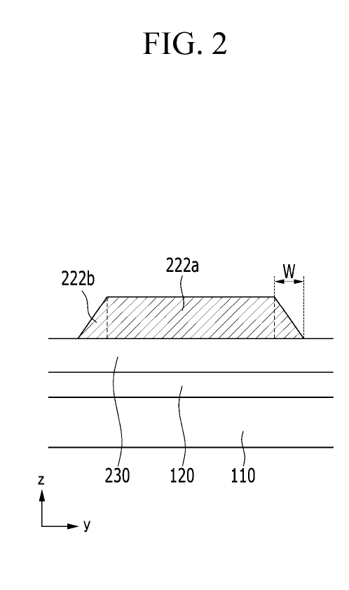

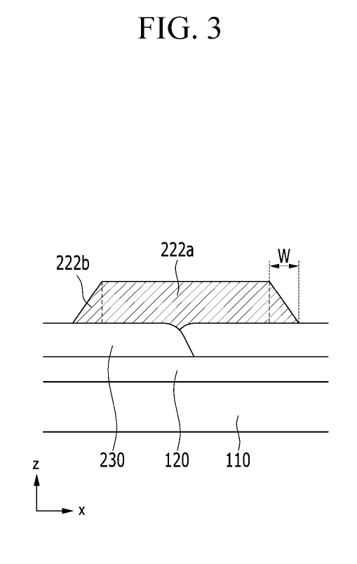

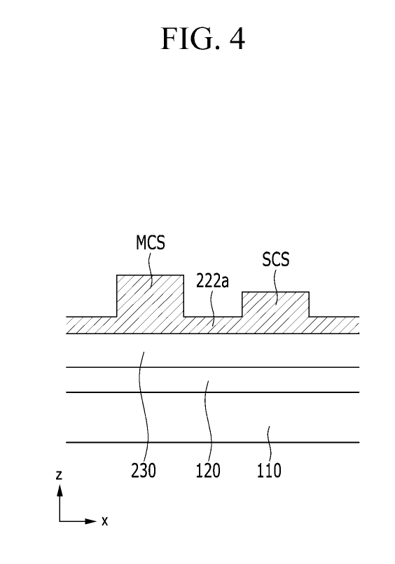

FIG. 1 shows a top plan view of a thin film transistor array panel according to an exemplary embodiment of the present disclosure. FIG. 2 shows a cross-sectional view with respect to line II-II of FIG. 1. FIG. 3 shows a cross-sectional view with respect to line of FIG. 1. FIG. 4 shows a cross-sectional view with respect to line IV-IV of FIG. 1.

Referring to FIG. 1 and FIG. 2, a film structure 120 including a thin film transistor is provided on a first substrate 110. The thin film transistor is a switching element and includes a control terminal, an input terminal, and an output terminal, which are described later.

Referring to FIG. 1 to FIG. 3, a plurality of color filters 230 are provided on the film structure 120. The color filters 230 may include a red color filter (R), a green color filter (G), and a blue color filter (B) sequentially disposed in an x direction of a lower substrate 110. Part of the edges of the neighboring color filters 230 may overlap each other.

The color filters 230 are arranged in the x direction, and they may be arranged in a y direction.

Here, the x direction represents a horizontal direction on a side of the lower substrate 110 and the y direction indicates a vertical direction thereon, such as shown in FIG. 1.

A light blocking member 220 is provided on the color filters 230. The light blocking member 220 includes a first light blocking member 220a extending in the x direction on the color filters 230 and a second light blocking member 220b extending in the y direction between the neighboring color filters 230.

Each of the first light blocking member 220a and the second light blocking member 220b includes a flat portion 222a and an inclined portion 222b. A top portion surface of the flat portion 222a is substantially flat, and the inclined portion 222b is provided to an external side of the flat portion 222a. A top portion surface of the inclined portion 222b may be substantially inclined. That is, the inclined portion 222b is provided at the external portion of the first light blocking member 220a and the second light blocking member 220b, and it gradually becomes thinner in a z direction when approaching the outermost edges of the first light blocking member 220a and the second light blocking member 220b from a portion that is near the flat portion 222a.

Therefore, an average thickness of the flat portion 222a in the z direction may be formed to be greater than an average thickness of the inclined portion 222b in the z direction.

The z direction is vertical to the x direction and the y direction and signifies a vertical direction when viewed from a side of the lower substrate 110.

A width (W) of the inclined portion 222b of the first light blocking member 220a in the y direction may be less than half the width of the entire second light blocking member 220b in the x direction.

A width (W) of the inclined portion 222b of the second light blocking member 220b in the x direction may be less than half the width of the second light blocking member 220b in the x direction.

When the width (W) of the inclined portion 222b of the light blocking member 220 is formed to be big, an arrangement angle of liquid crystal molecules overlapping the inclined portion 222b may be changed such that light may leak or transmittance may be reduced. The light blocking member 220 according to the present exemplary embodiment minimizes the width (W) of the inclined portion 222b to prevent changes to the arrangement angle of the liquid crystal molecules and prevent light leakage and transmittance reduction.

As shown in FIG. 4, the first light blocking member 220a may further include a main column spacer (MCS) and a sub column spacer (SCS) that are provided separately from each other.

The main column spacer (MCS) and the sub column spacer (SCS) may be integrally formed of a same material as the first light blocking member 220a, and a height of an upper side of the main column spacer (MCS) from the lower substrate 110 may be greater than a height of an upper side of the sub column spacer (SCS) from the lower substrate 110. That is, the thickness of the sub column spacer (SCS) in the z direction may be less than the thickness of the main column spacer (MCS) in the z direction.

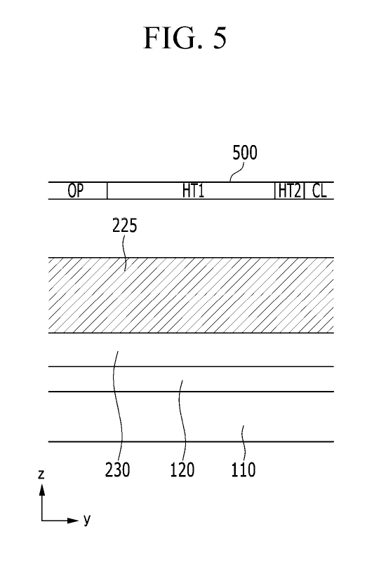

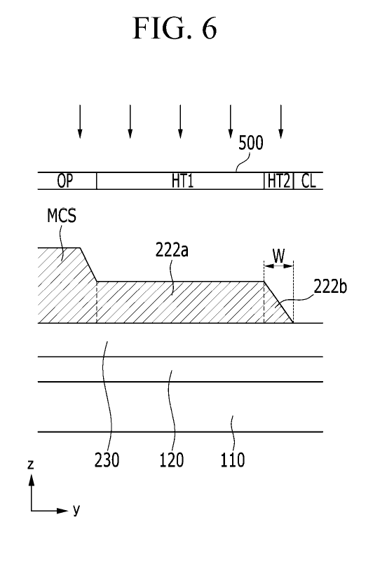

A method for forming a light blocking member 220 of a thin film transistor array panel according to the present exemplary embodiment is now described with reference to FIG. 5 and FIG. 6.

FIG. 5 and FIG. 6 show cross-sectional views for describing a process for forming a light blocking member of a thin film transistor array panel according to an exemplary embodiment of the present disclosure with respect to line V-V of FIG. 1.

As shown in FIG. 5, the film structure 120 including a thin film transistor and the color filter 230 are formed on the lower substrate 110, and a light blocking material layer 225 is formed on the color filter 230.

The light blocking material layer 225 is exposed by using a mask 500.

The mask 500 includes a plurality of regions with different transmittances, and the regions may show at least four different transmittances.

The regions showing four transmittances may include a light transmitting region OP with the greatest light transmittance, a first transflective region HT1 for transmitting part of the light, a second transflective region HT2 for transmitting part of the light and having a different transmittance than the first transflective region, and a light blocking region CL with the lowest light transmittance.

The first transflective region HT1 may be provided on an edge of the light transmitting region OP, and the second transflective region HT2 may be provided along an edge of the first transflective region.

The light transmitting region OP may transmit most of the light so its light transmittance may be about 100%, the light blocking region CL may block most of the light so its light transmittance may be about 0%, the first transflective region HT1 may have light transmittance of about 14-18%, and the second transflective region HT2 may have light transmittance of about 7-11%.

When the light is irradiated to the light blocking material layer 225 having negative photosensitivity (i.e., portions irradiated with light remains), the light blocking region CL of the mask 500 may correspond to a region in which the light blocking member 220 is not formed, the light transmitting region OP may correspond to a position where the main column spacer (MCS) or the sub column spacer (SCS) is formed, the first transflective region HT1 may correspond to a flat portion 222a of the light blocking member 220, and the second transflective region HT2 may correspond to a position where an inclined portion 222b of the light blocking member 220 is formed.

Referring to FIG. 6, the light blocking member 220 including the column spacers (MCS and SCS), the flat portion 222a, and the inclined portion 222b may be formed according to the exposure using the mask 500.

In the present exemplary embodiment, the width (W) of the inclined portion 222b provided on the external side of the light blocking member 220 may be reduced by including the first transflective region HT1 and the second transflective region HT2 with different transmittances of the mask 500.

Differing from the present exemplary embodiment, when the light blocking member 220 is exposed by using a mask including a single transflective region, part of the light reaches a space between the mask and the light blocking member 220 such that the width (W) of the inclined portion 222b provided on the external side of the light blocking member 220 is formed to be relatively wide compared to the present exemplary embodiment. When the inclined portion 222b is formed to be relatively wide as described, an arrangement of liquid crystal molecules provided at a top portion of the inclined portion 222b is changed to possibly leak light and deteriorate transmittance.

Therefore, when the light blocking member 220 is formed by using a mask including two transflective regions according to the present exemplary embodiment, light leakage and transmittance deterioration may be prevented compared to the case in which the width (W) of the inclined portion 222b of the light blocking member 220 is formed to be relatively wide.

Differing from the above-described exemplary embodiment, when the light blocking material layer 225 has positive photosensitivity, transmittance of the mask 500 may be opposite to the above-described exemplary embodiment.

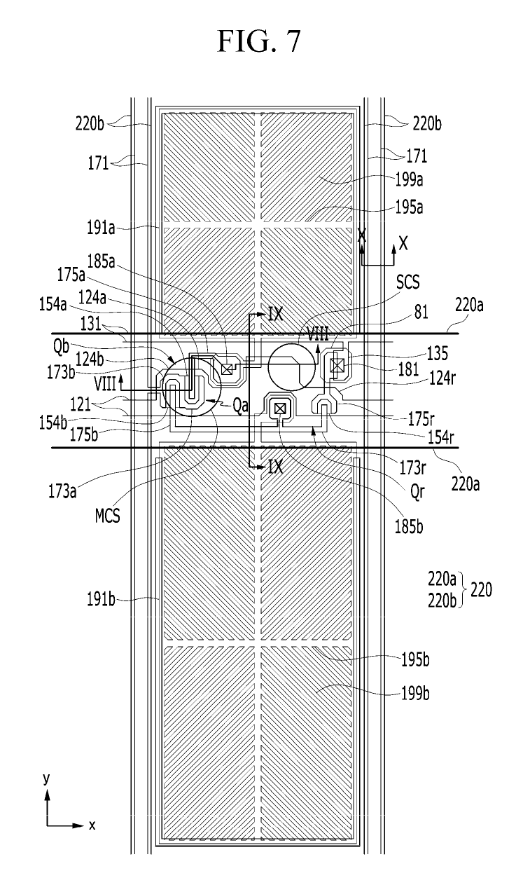

A liquid crystal display according to an exemplary embodiment of the present disclosure is now described with reference to FIG. 7 to FIG. 10.

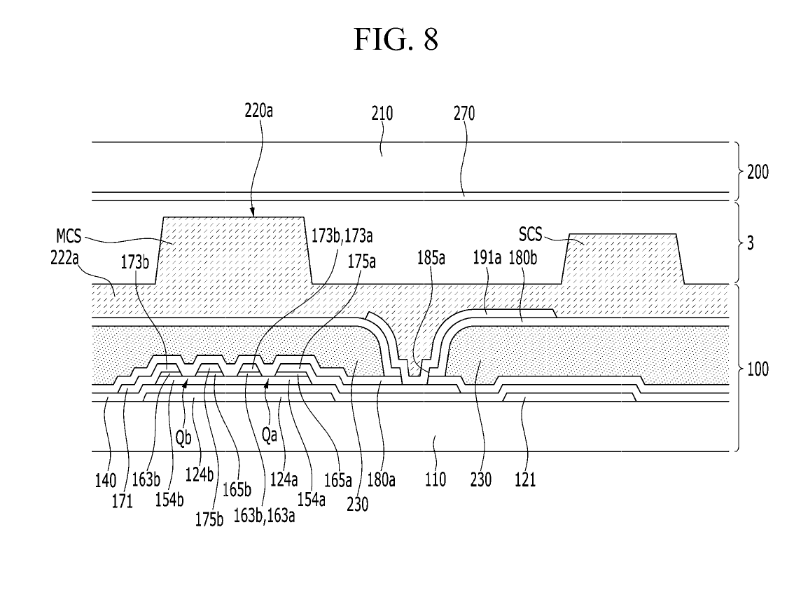

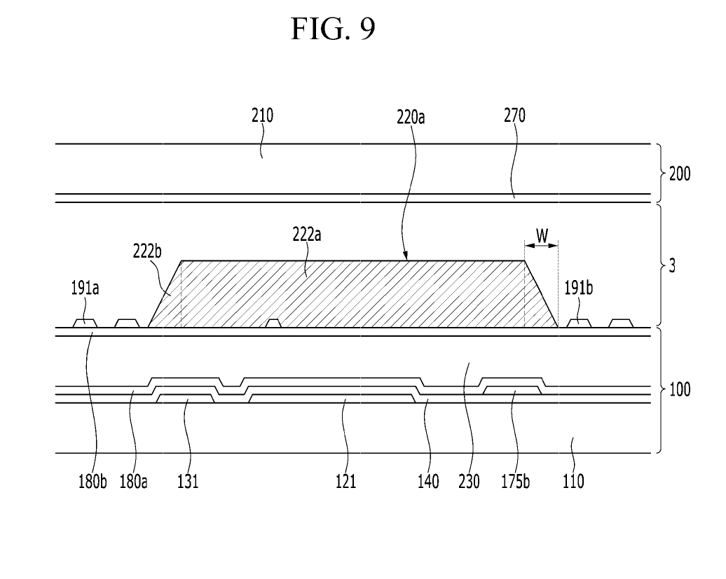

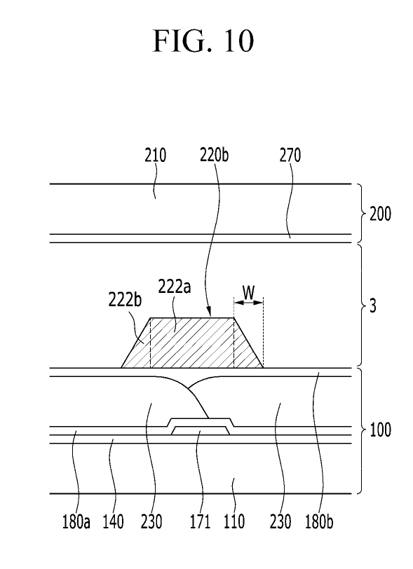

FIG. 7 shows a top plan view of a pixel of a liquid crystal display according to an exemplary embodiment of the present disclosure. FIG. 8 shows a cross-sectional view with respect to line VIII-VIII of FIG. 7. FIG. 9 shows a cross-sectional view with respect to line IX-IX of FIG. 7. FIG. 10 shows a cross-sectional view with respect to line X-X of FIG. 7.

The liquid crystal display may include a lower panel 100 and an upper panel 200 facing each other, and a liquid crystal layer 3 provided between the display panels 100 and 200.

Regarding the lower panel 100, a gate conductor including a plurality of gate lines 121 and a reference voltage line 131 is provided on a lower substrate 110.

The gate lines 121 may mainly extend in the x direction and may include a first gate electrode 124a, a second gate electrode 124b, and a third gate electrode 124r protruding in the y direction.

The reference voltage line 131 may be separated from the gate line 121 and may mainly extend in the x direction. The reference voltage line 131 may transmit a reference voltage that may be an AC voltage (AC) or a DC voltage (DC) such as a common voltage Vcom.

The reference voltage line 131 may include a protrusion 135 protruding upward or downward from a portion extending in the x direction.

A gate insulating layer 140 is provided on the gate conductor, and a semiconductor layer including a first semiconductor 154a, a second semiconductor 154b, and a third semiconductor 154r is provided thereon. The first semiconductor 154a may be connected to the second semiconductor 154b. The first semiconductor 154a may overlap the first gate electrode 124a, the second semiconductor 154b may overlap the second gate electrode 124b, and the third semiconductor 154r may overlap the third gate electrode 124r.

The semiconductor layer may include amorphous silicon, polycrystalline silicon, or metal oxide.

A plurality of ohmic contacts (163a, 163b, 165a, and 165b) may be provided on the semiconductor layer. The ohmic contacts (163a, 163b, 165a, and 165b) may be made of a material such as a silicide or n+ hydrogenated amorphous silicon to which a highly concentrated n-type impurity is doped. The ohmic contacts (163a, 163b, 165a, and 165b) may be omitted.

A data conductor including a plurality of data lines 171, a first source electrode 173a, a second source electrode 173b, a first drain electrode 175a, a second drain electrode 175b, a third source electrode 173r, and a third drain electrode 175r are provided on the ohmic contacts (163a, 163b, 165a, and 165b) and the gate insulating layer 140.

The data lines 171 may transmit a data signal and may extend in the y direction to cross the gate line 121 and the reference voltage line 131.

The first source electrode 173a protrudes to the first gate electrode 124a from the data line 171 to face the first drain electrode 175a, and the second source electrode 173b protrudes to the second gate electrode 124b from the data line 171 to face the second source electrode 173b.

The first source electrode 173a is connected to the second source electrode 173b, and the second drain electrode 175b is connected to the third source electrode 173r. The third source electrode 173r faces the third drain electrode 175r.

One end portion not facing the third source electrode 173r from among end portions of the third drain electrode 175r may neighbor or overlap part of the protrusion 135 of the reference voltage line 131.

The first gate electrode 124a, the first source electrode 173a, the first drain electrode 175a, and the first semiconductor 154a together configure a first thin film transistor Qa, which is a first switching element. The second gate electrode 124b, the second source electrode 173b, the second drain electrode 175b, and the second semiconductor 154b together configure a second thin film transistor Qb, which is a second switching. The third gate electrode 124r, the third source electrode 173r, the third drain electrode 175r, and the third semiconductor 154r together configure a third thin film transistor (Qr), which is a voltage-dividing switching element.

Channels of the first thin film transistor (Qa), the second thin film transistor (Qb), and the third thin film transistor (Qr) are formed on the first, second, and third semiconductors 154a, 154b, and 154r between the first, second, and third source electrodes 173a, 173b, and 173r and the first, second, and third drain electrodes 175a, 175b, and 175r.

The gate line 121, the reference voltage line 131, and the first to third thin film transistors (Qa, Qb, and Qr) may be provided to overlap the first light blocking member 220a shown in FIG. 1.

The configuration of the above-described thin film transistor is not limited, and it may be modified to fit various kinds of configurations including at least one thin film transistor.

A first insulating layer 180a is provided on the data conductor and the exposed semiconductors 154a, 154b, and 154r. The first insulating layer 180a may be made of an organic insulating material or an inorganic insulating material, and may include a single layer or multiple layers.

A color filter 230 may be provided on the first insulating layer 180a. The color filter 230 may display one primary color, such as one of the three primary colors of red, green, and blue, or four primary colors. The color filter 230 may display one of cyan, magenta, yellow, and white based primary colors and is not limited to the three primary colors.

The color filter 230 may extend along a corresponding pixel array. The color filter 230 may include an opening (not shown) respectively provided in part of the first and second drain electrodes 175a and 175b.

A second insulating layer 180b may be further provided on the color filter 230. The second insulating layer 180b may include an inorganic insulating material or an organic insulating material. The second insulating layer 180b, an overcoat for the color filter 230, may prevent the color filter 230 from being exposed and provide a flat surface. The second insulating layer 180b may prevent an impurity, such as a pigment of the color filter 230, from being input to the liquid crystal layer 3. The second insulating layer 180b may be omitted in some cases.

The first insulating layer 180a and the second insulating layer 180b include a first contact hole 185a for exposing part of the first drain electrode 175a and a second contact hole 185b for exposing part of the second drain electrode 175b. The first and second contact holes 185a and 185b may be provided in the opening of the color filter 230.

The gate insulating layer 140 and the first and second insulating layers 180a and 180b may further include a contact hole 181 for exposing part of the third drain electrode 175r and part of the protrusion 135 of the reference voltage line 131.

A plurality of pixel electrodes and a plurality of contact assistants 81 are provided on the second insulating layer 180b.

One pixel electrode may be formed with an electrode or may include a plurality of subpixel electrodes. The present exemplary embodiment focuses on the example in which one pixel electrode includes a first subpixel electrode 191a and a second subpixel electrode 191b.

The first subpixel electrode 191a may face the second subpixel electrode 191b with a gate line 121, a reference voltage line 131, and first to third thin film transistors (Qa, Qb, and Qr) therebetween. However, the arrangements and shapes of the first subpixel electrode 191a and the second subpixel electrode 191b are not limited, but may be modified in various ways.

For example, the first subpixel electrode 191a and the second subpixel electrode 191b may be quadrangular. The first subpixel electrode 191a and the second subpixel electrode 191b may respectively include cross-shaped stems 195a and 195b including a horizontal stem and a vertical stem and a plurality of fine branches 199a and 199b extending outward from the cross-shaped stems 195a and 195b.

The first subpixel electrode 191a and/or the second subpixel electrode 191b may be divided into a plurality of subregions by the cross-shaped stems 195a and 195b. The fine branches 199a and 199b may extend from the cross-shaped stems 195a and 195b in an oblique manner, and their extending direction may form an angle of about 45 or 135 degree with respect to the gate line 121. The extending directions of the fine branches 199a and 199b of the neighboring subregions are different, and for example, they may be orthogonal to each other.

The first subpixel electrode 191a and the second subpixel electrode 191b may respectively further include an external stem (not shown) for surrounding the external side.

The first subpixel electrode 191a and the second subpixel electrode 191b are physically and electrically connected to the first drain electrode 175a and the second drain electrode 175b through contact holes 185a and 185b. The first subpixel electrode 191a may receive a data voltage from the first drain electrode 175a, and the second subpixel electrode 191b may receive a divided voltage between the data voltage transmitted through the second drain electrode 175b and the reference voltage transmitted by the reference voltage line 131.

The third drain electrode 175r may be connected to the protrusion 135 of the reference voltage line 131 through a contact assistant 81 in the contact hole 181.

The first subpixel electrode 191a, the second subpixel electrode 191b, and the contact assistant 81 may include a transparent conductive material, such as an indium tin oxide (ITO), an indium zinc oxide (IZO), or a metal thin film.

The disposal and shape of the pixel, the structure of the thin film transistor, and the shape of the pixel electrode described in the present exemplary embodiment are one example, and numerous variations are allowable.

A light blocking member 220 is provided on the first and second subpixel electrodes 191a and 191b and the contact assistant 81.

The light blocking member 220 includes a flat portion 222a having an upper side that is substantially flat and an inclined portion 222b provided on an external side of the flat portion 222a and that is substantially inclined, and it includes a first light blocking member 220a overlapping the gate line 121 and a second light blocking member 220b overlapping the data line 171.

An average thickness of the flat portion 222a in the z direction may be formed to be greater than an average thickness of the inclined portion 222b in the z direction.

The first light blocking member 220a may further include a main column spacer (MCS) and a sub column spacer (SCS).

The flat portion 222a of the first light blocking member 220a may overlap the first to third thin film transistors (Qa, Qb, and Qr) and may have a substantially flat upper side. The first light blocking member 220a may block the light between the first subpixel electrode 191a and the second subpixel electrode 191b. The first light blocking member 220a may include a portion for covering the contact holes (185a, 185b, and 181), and the portion may fill a big step on top portions of the contact holes (185a, 185b, and 181), flatten a surface, and prevent light leakage.

The inclined portion 222b of the first light blocking member 220a is provided near the first subpixel electrode 191a and the second subpixel electrode 191b and may have a slanted side.

The width (W) of the inclined portion 222b of the first light blocking member 220a in the y direction may be less than half the width of the second light blocking member 220b in the x direction.

The main column spacer (MCS) and the sub column spacer (SCS) may be separated from each other, and they may be integrally formed with the first light blocking member 220a and may be made of a same material.

The main column spacer (MCS) and the sub column spacer (SCS) may be provided on top portions of the first to third thin film transistors (Qa, Qb, and Qr) and/ or the signal lines such as the gate line 121, the reference voltage line 131, and the data line 171. For example, the main column spacer (MCS) may be provided on the top portions of the first and second thin film transistors (Qa and Qb), and the sub column spacer (SCS) may be provided near the thin film transistor, that is, an external upper side of the region in which the thin film transistor is provided, (e.g., the top portion of the gate line 121), but they are not limited thereto.

The main column spacer (MCS) and the sub column spacer (SCS) are sub spacers for maintaining and supporting a cell gap between the upper panel 200 and the lower panel 100 when a distance between the upper panel 200 and the lower panel 100 of the liquid crystal display is reduced by an external pressure.

The flat portion 222a of the second light blocking member 220b may overlap the data line 171 and may have a substantially flat upper side. The second light blocking member 220b may block the light between the neighboring pixels.

The inclined portion 222b of the second light blocking member 220b may be provided near the first subpixel electrode 191a and the second subpixel electrode 191b and may have a slanted side.

The width (W) of the inclined portion 222b of the second light blocking member 220b in the x direction may be less than half the width of the entire second light blocking member 220b in the x direction.

When the width (W) of the inclined portion 222b of the light blocking member 220 is formed to be relatively wide compared to the present embodiment, an arrangement angle of liquid crystal molecules overlapping the inclined portion 222b on the inclined portion 222b may be changed such that light may leak or transmittance may be reduced. The light blocking member 220 according to the present exemplary embodiment minimizes the width (W) of the inclined portion 222b to prevent the changes of the arrangement angle of the liquid crystal molecules and prevent light leakage and transmittance reduction.

An alignment layer (not shown) may be formed on the light blocking member 220, and in this case, the alignment layer may be a vertical alignment layer.

Regarding the upper panel 200, a common electrode 270 may be provided toward the lower substrate 110 on the upper substrate 210. The common electrode 270 may be a planar shape and may be formed on the entire surface of the upper substrate 210 as a whole plate. The common electrode 270 may transmit a predetermined common voltage Vcom. The common electrode 270 may include a transparent conductive material such as an ITO, an IZO, or a metal thin film.

An alignment layer (not shown) may be formed on the common electrode 270, and in this case, the alignment layer may be a vertical alignment layer.

The liquid crystal layer 3 includes a plurality of liquid crystal molecules (not shown). The liquid crystal molecules may have negative dielectric anisotropy, and they may be aligned to be vertical to the substrates 110 and 210 when no electric field is generated in the liquid crystal layer 3. The liquid crystal molecules may form a pretilt in a predetermined direction when no electric field is generated in the liquid crystal layer 3. For example, the liquid crystal molecules may form a pretilt substantially parallel to the fine branches 199a and 199b of the first and second subpixel electrodes 191a and 191b and may be inclined.

The first subpixel electrode 191a forms a first liquid crystal capacitor together with the common electrode 270, and the second subpixel electrode 191b forms a second liquid crystal capacitor together with the common electrode 270 to maintain a charged voltage.

According to exemplary embodiments of the thin film transistor array panel and the manufacturing method thereof disclosed herein, the residual region of the light blocking member may be minimized to prevent the light leakage of the display device and improve the transmittance.

While this disclosure has been described in connection with exemplary embodiments, it is to be understood that the invention is not limited to the disclosed embodiments. On the contrary, it is intended to cover various modifications and equivalent arrangements included within the spirit and scope of the appended claims.

What is claimed is:

1. A thin film transistor array panel comprising:
a substrate;
a gate line provided on the substrate and extending in a first direction;
a data line extending in a second direction;
a first light blocking member provided on the gate line and the data line and overlapping the gate line, and
a second light blocking member overlapping the data line,
wherein the first and second light blocking members respectively include a flat portion and an inclined portion having different average thicknesses in a third direction that is vertical to the first direction and second direction,
the inclined portion has a slanted side at an external portion of the flat portion, and
a width of the inclined portion of the first light blocking member in the second direction is less than half the width of the second light blocking member in the first direction.

2. The thin film transistor array panel of claim 1, wherein
a width of the inclined portion of the second light blocking member in the first direction is less than half the width of the second light blocking member in the first direction.

3. The thin film transistor array panel of claim 2, wherein
an upper side of the flat portion is substantially flat, and
a thickness of the inclined portion in the third direction is reduced when approaching outermost edges of the first and second light blocking members from a portion provided near the flat portion.

4. The thin film transistor array panel of claim 2, wherein
the first light blocking member includes a column spacer having a thickness in the third direction that is greater than the inclined portion and the flat portion.

5. The thin film transistor array panel of claim 4, wherein
the column spacer includes a main column spacer and a sub column spacer, and
a thickness of the main column spacer in the third direction is greater than a thickness of the sub column spacer in the third direction.

6. The thin film transistor array panel of claim 5, wherein
the column spacer is integrated with the first and second light blocking members.

7. The thin film transistor array panel of claim 6, wherein
the column spacer includes a same material as the light blocking member.

8. A method for manufacturing a thin film transistor array panel comprising:
forming a gate line in a first direction and a data line in a second direction on a substrate;
forming a light blocking material layer on an entire side of the substrate; and
forming a first light blocking member and a second light blocking member including a flat portion and an inclined portion having different average thicknesses in a third direction that is vertical to the first direction and the second direction by exposure using a mask,
wherein the first light blocking member overlaps the gate line and the second light blocking member overlaps the data line,
the inclined portion has a slanted side on an external portion of the flat portion, and
the mask transmits part of the light and includes a first transflective region and a second transflective region with different light transmittances.

9. The method of claim 8, wherein
a width of the inclined portion of the first light blocking member in the second direction is formed to be less than half the width of the second light blocking member in the first direction, and
a width of the inclined portion of the second light blocking member in the first direction is less than half the width of the second light blocking member in the first direction.

10. The method of claim 9, wherein
the second transflective region is formed along an edge of the first transflective region, and
light transmittance of the first transflective region is greater than light transmittance of the second transflective region.

11. The method of claim 10, wherein
the first transflective region corresponds to the flat portion, and
the second transflective region corresponds to the inclined portion.

12. The method of claim 11, wherein
light transmittance of the first transflective region is substantially 14 to 18%, and
light transmittance of the second transflective region is substantially 7 to 11%.

13. The method of claim 11, wherein
the forming of a first light blocking member includes
forming a column spacer having a height in the third direction that is greater than those of the inclined portion and the flat portion of the first light blocking member.

14. The method of claim 13, wherein
the mask further includes a light transmitting region for transmitting the entire light, and
the light transmitting region corresponds to the column spacer.

15. The method of claim 8, further comprising,
forming a color filter on the substrate before the forming of a light blocking material layer.
